(19) United States
(12) Patent Application Publication
(10) Pub. No.: US 2017/0219330 A1
(43) Pub. Date: Aug. 3, 2017

(54) DISPLACEMENT SENSING APPARATUS AND METHODS

(71) Applicant: TouchNetix Limited, Fareham, Hampshire (GB)

(72) Inventors: Peter Timothy Sleeman, Waterlooville, Hants (GB); Stephen William Roberts, Winchester, Hants (GB)

(21) Appl. No.: 15/500,363

(22) PCT Filed: Jul. 23, 2015
(86) PCT No.: PCT/GB2015/052127

§ 371 Date: Jan. 30, 2017

(30) Foreign Application Priority Data
Jul. 31, 2014 (GB) 1413563.6

(51) Int. Cl. G01B 7/14; H03K 17/975

(52) U.S. Cl. CPC G01B 7/14; H03K 17/975; H03K 2217/9651

(57) ABSTRACT

A displacement sensor comprising: a reference electrode; and a displacement element movably mounted relative to the reference electrode and comprising a substrate having first and second opposing surfaces with a first electrode arranged around a peripheral part of the first surface and a second electrode arranged around a peripheral part of the second surface, and wherein the reference electrode on the same side of the substrate as the second electrode and offset therefrom; and a controller element configured to measure a capacitance characteristic of the second electrode at different times and to determine whether there has been a displacement of the displacement element relative to the reference electrode based on whether there has been a change in the capacitance characteristic of the second electrode.

### BACKGROUND OF THE INVENTION

The present invention relates to the field of displacement sensing, and in particular to capacitance-based displacement sensing methods and apparatus, for example to detect when an object presses on a moveable surface.

Capacitive sensing techniques have become widespread for providing touch-sensitive inputs, for example in computer tablets, mobile phones, and in many other applications. Touch sensitive input devices are generally perceived to be more aesthetically pleasing than input devices that are based on mechanical switches. Nonetheless, the present inventors have recognised there are still situations in which a user-interface that is responsive to mechanical input may be desired. In particular, the inventors have recognised there are situations in which there is a desire to measure the physical displacement of a displacement element, for example to provide the equivalent of a “click” when navigating a cursor across a display screen using a touch sensor. Furthermore, the inventors have recognised it can be desirable to provide such functionality using capacitive sensing techniques rather than mechanical switching techniques. Not only can capacitive sensing techniques provide for more reliable sensors (as they are less prone to mechanical wear), there may be situations in which displacement sensing is desired in conjunction with other sensors based on capacitive sensing (for example to measure the displacement of a capacitive touch screen), and so it can be convenient to adopt the same sensing technologies for both touch position and displacement sensing aspects.

One issue with using capacitive techniques for sensing the displacement of an object is the potential for whatever is causing the displacement, such as a user's finger pressing on the object, to affect the capacitance measurements associated with the displacement sensor in addition to the effect of the displacement itself. Another issue with capacitive sensing is the potential for non-uniformity in response, for example depending on where the activation load is applied to the object being displaced (i.e. whether in the middle or towards an edge).

There is therefore a desire for apparatus and methods to help reliably sense the displacement of an object relative to another object using capacitive sensing techniques.

### SUMMARY OF THE INVENTION

According to a first aspect of the invention there is provided a displacement sensor comprising: a reference electrode; and a displacement element movably mounted relative to the reference electrode and comprising a substrate having first and second opposing surfaces with a first electrode arranged around a peripheral part of the first surface and a second electrode arranged around a peripheral part of the second surface, and wherein the reference electrode is on the same side of the substrate as the second electrode and offset therefrom; and a controller element configured to measure a capacitance characteristic of the second electrode to determine a displacement of the displacement element relative to the reference electrode from the measured capacitance characteristic of the second electrode.

According to some examples the displacement sensor further comprises a frame element to which the displacement element is movably mounted.

According to some examples the reference electrode is provided by the frame element.

According to some examples the frame element comprises a conductive material and/or has a conductive material disposed thereon to provide the reference electrode.

According to some examples the displacement element is movably mounted to the frame element using a resiliently compressible support element.

According to some examples the displacement element and/or the frame element are bonded to the support element.

According to some examples the support element extends around the periphery of the substrate element to provide a seal for the displacement sensor.

According to some examples the displacement sensor further comprises a cover panel arranged over the substrate on the same side of the substrate as the first electrode.

According to some examples the first and/or second electrodes form a closed path.

According to some examples the second electrode comprises regions of different widths on the substrate at different positions around the substrate.

According to some examples the second electrode comprises a series of primary sensing regions linked by conductive traces which are narrower than the primary sensing regions.

According to some examples the first electrode has an extent on the substrate which substantially covers the extent of the second electrode.

According to some examples the first electrode has an extent on the substrate which goes beyond the extent of the second electrode.

According to some examples the displacement sensor is configured such that the reference electrode and/or the first electrode is connected to a reference potential when the capacitance characteristic of the second electrode is being measured.

According to some examples the controller element is configured to measure the capacitance characteristic of the second electrode with respect to the reference electrode by measuring the second electrode's response to a time-varying drive signal applied to the second electrode.

According to some examples the displacement sensor is configured such that the first electrode is connected to a reference potential when the capacitance characteristic of the second electrode is being measured.

According to some examples the controller element is configured to apply a time-varying drive signal to the first electrode based on the time-varying drive signal applied to the second electrode when the capacitance characteristic of the second electrode is being measured.

According to some examples the controller element is configured to measure the capacitance characteristic of the second electrode by applying a time-varying drive signal to the first electrode and/or the reference electrode and measuring the extent to which the drive signal is coupled to second electrode.

According to some examples the controller element is configured to measure the capacitance characteristic of the second electrode by applying a time-varying drive signal to the second electrode and measuring the extent to which the drive signal is coupled to the reference electrode.

According to some examples the second electrode comprises a first part and a second part, and wherein the controller element is configured to measure the capacitance characteristic of the second electrode by applying a time-varying drive signal to one of the first and second parts of the second electrode and measuring the extent to which the drive signal is coupled to the other of the first and second parts of the second electrode.

According to some examples the capacitance characteristic of the second electrode comprises an indication of the second electrode's mutual-capacitance with respect to the first electrode and/or reference electrode.

According to some examples the capacitance characteristic of the second electrode comprises an indication of the second electrode's self-capacitance.

According to some examples the controller element is further configured to generate an output signal to indicate when it determines there has been a displacement of the displacement element relative to the reference electrode.

According to some examples the control element is configured to determine there has been a displacement of the displacement element relative to the reference electrode by comparing a difference between two measurements of the capacitance characteristic with a trigger threshold.

According to some examples the displacement sensor further comprises a position-sensitive capacitive touch sensor having an electrode pattern defining a sensitive area for the position-sensitive capacitive touch sensor on the substrate.

According to a second aspect of the invention there is provided an apparatus comprising the displacement sensor of the first aspect of the invention.

According to a third aspect of the invention there is provided a method of sensing displacements, comprising: providing a reference electrode; providing a displacement element movably mounted relative to the reference electrode and comprising a substrate having first and second opposing surfaces with a first electrode arranged around a peripheral part of the first surface and a second electrode arranged around a peripheral part of the second surface, and wherein the reference electrode is on the same side of the substrate as the second electrode and offset therefrom; measuring a capacitance characteristic of the second electrode; and determining a displacement of the displacement element relative to the reference electrode from the measured capacitance characteristic of the second electrode.

It will be appreciated that features and aspects of the invention described above in relation to the first and other aspects of the invention are equally applicable to, and may be combined with, embodiments of the invention according to other aspects of the invention as appropriate, and not just in the specific combinations described above.

### BRIEF DESCRIPTION OF THE DRAWINGS

The invention is now described by way of example only with reference to the following drawings in which:

FIG. 1A schematically represents a displacement element in plan-view and controller element of a displacement sensor according to certain embodiments of the invention;

FIG. 1B the schematically shows the displacement element of FIG. 1A in cross-section view;

FIG. 2 schematically represents the displacement element and controller element of FIGS. 1A and 1B along with other elements of a displacement sensor according to certain embodiments of the invention; and

FIG. 3 schematically represents a displacement element in plan-view according to certain other embodiments of the invention.

### DETAILED DESCRIPTION

Aspects and features of certain examples and embodiments of the present invention are discussed/described herein. Some aspects and features of certain examples and embodiments may be implemented conventionally and these are not discussed/described in detail in the interests of brevity. It will thus be appreciated that aspects and features of apparatus and methods discussed herein which are not described in detail may be implemented in accordance with any conventional techniques for implementing such aspects and features.

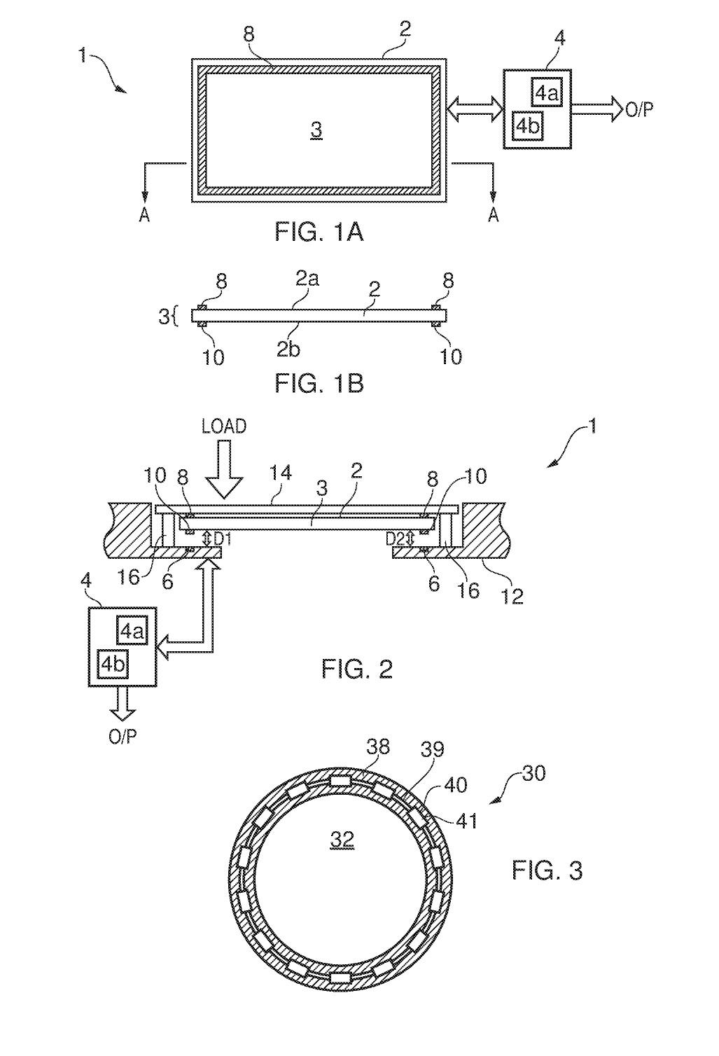

FIGS. 1A, 1B and 2 schematically represent various aspects of a displacement sensor 1 in accordance with certain embodiments of the invention. The displacement sensor 1 comprises three main functional elements, namely a displacement element 3, a frame element 12 and a controller element 4. FIG. 1A shows the displacement element 3 in plan-view and the controller element 4 in highly schematic form. FIG. 1B schematically shows the displacement element 3 in cross-section along the line A-A identified in FIG. 1A). FIG. 2 schematically shows the displacement element 3 in cross-section along the line A-A identified in FIG. 1A as well as the frame element 12 and some other elements of the displacement sensor as discussed further below. FIG. 2 also shows the controller element 4 in highly schematic form (i.e. as a functional block). The displacement element 3 comprises a substrate 2 having a first surface 2a and a second surface 2b. The substrate 2 defines the general overall shape of the displacement element 3, and is in this example in the form of a planar rectangle, but other shapes may be used. The size of the substrate may be chosen according to the implementation at hand (i.e. the desired size of the displacement sensor). Purely for the sake of a specific example, it will be assumed here the substrate has a size of around 12 cm (width)×8 cm (height)×0.3 cm (thickness). The first 2a and second 2b surfaces of the substrate 2 are the opposing largest faces.

The substrate 2 is formed of a non-conductive material, for example a glass or plastic material. The substrate 2 may be transparent or opaque according to the application at hand.

For example, in some example implementations a display screen may be provided below the displacement element, and in this case the substrate should be transparent, at least to some extent, to allow a user to see the screen through the displacement element. In other cases there may be a desire from a design perspective to hide what is behind the displacement sensor (for example because there is internal wiring or structural elements of an apparatus in which the displacement sensor is mounted which are not intended to be visible to the user for aesthetic reasons), and in this case the substrate may be opaque. Purely for the sake of a specific example, it will be assumed here the substrate is comprised of a material of the kind conventionally used for printed circuit boards (e.g. a glass fibre reinforced epoxy resin).

The displacement element 3 is the part of the displacement sensor 1 to which a load is applied during use (e.g. by a user pressing on the displacement element 3) to cause movement of the displacement element 3 relative to the frame element 12 (or more particularly, relative to a reference/frame electrode 6 associated with the frame element 12, as discussed further below). It is this movement which is sensed by the displacement sensor 1. The load may be applied directly to the surface of the substrate or indirectly, for example, depending on whether a cover layer/panel is provided.

The first surface 2a of the substrate 2 (i.e. the surface represented in the plan view of FIG. 1A and shown uppermost in the cross-section views of FIGS. 1B and 2) is, in this example, taken to be on the same side of the substrate as the direction from which a load is applied during normal use. The application of an example load during use, e.g. corresponding to a user pressing a finger on the displacement element 1, is schematically shown in FIG. 2 by the arrow labelled “LOAD”. For ease of explanation, the side of the displacement sensor 1 to which the load is applied in normal use may sometimes be referred to herein as the “upper” or “outer” side of the displacement sensor (or similar terminology such as “top”), with the other side being referred to as “lower” or “inner” (or similar terminology, such as “bottom”). Thus, the first surface 2a of the displacement element 3 may sometimes be referred to as the upper/outer/top surface of the substrate 2. Likewise, the second surface 2b may sometimes be referred to as the bottom/lower/inner surface of the substrate 2. However, it will be appreciated this terminology is used purely for convenience of explanation, and is not intended to suggest a particular orientation of the displacement sensor 1 should be adopted in normal use. For example, in the orientation of FIG. 2 the upper surface of the displacement sensor is shown uppermost, but the displacement sensor could equally be used in a downward facing configuration, or facing outwards from a vertical surface according to the implementation at hand. More generally, the displacement sensor may be incorporated in a portable apparatus (such as a tablet computer or mobile telephone), and so the orientation in use will vary according to how a user happens to be holding the apparatus.

A first electrode 8 is provided at the periphery/in a peripheral part of the first surface 2a of the substrate 2 (i.e. adjacent to/in the vicinity of an outer edge of the first surface 2a). In this particular example the first electrode 8 forms a substantially closed path (i.e. closed or nearly closed) around the entire periphery of the substrate and has a uniform width of around 0.1 cm and is separated from the outer edge of the first surface 2 by a similar distance, but could in some cases extend all the way to the edge. However, it will be appreciated the specific geometry of the first electrode, e.g. in terms of its width and separation from the edge of the first surface 2a and the extent to which it extends around the whole periphery, may be different in different implementations. The first electrode may be provided on the substrate in accordance with conventional techniques for applying conductive traces to substrates. For example, in this case where the substrate comprises a printed circuit board material, the first electrode 8 may comprise copper foil bonded to the substrate in the appropriate pattern, for example using conventional printed circuit board manufacturing techniques. However, it will be appreciated that other techniques can be used in other implementations. For example, in a case where the substrate comprises a transparent material, the first electrode 8 may be formed of a transparent conductive material, such as indium tin oxide ITO, again in accordance with conventional techniques.

A second electrode 10 is provided at the periphery/in a peripheral part of the second surface 2b of the substrate 2 (i.e. adjacent to/in the vicinity of an outer edge of the second surface 2b). The arrangement of the second electrode 10 on the second surface corresponds with the arrangement of the first electrode 8 on the first surface. That is to say, the first and second electrodes are generally in alignment (with regards to a direction perpendicular to the substrate) and have corresponding extents on their respective surfaces. Thus, the extent of the first electrode 8 substantially covers (i.e. totally covers or nearly totally covers) the extent of the second electrode 10 when viewed from above (hence the second electrode is not visible in the plan view of FIG. 1A). As with the first electrode 8, the second electrode 10 may be provided on the substrate in accordance with conventional techniques.

It will be appreciated the first and second electrodes will generally be relatively thin compared to the thickness of the substrate, but the figures are not drawn to scale and the electrodes are shown with exaggerated thickness in the cross-sections of FIGS. 1A and 2 for ease of representation.

In addition to the displacement element 3, the frame element 12 and the controller 4, the displacement sensor 1 in this particular example further includes a cover layer/panel 14 which is arranged to overlie the displacement element 3 with the displacement element 3 bonded thereto (as schematically represented in FIG. 2). The cover layer 14 in this particular example has a size which overhangs the displacement element 3 by around 1 cm around the entire periphery of the displacement element 3. The displacement element 3 may be bonded to the cover layer 14 in accordance with conventional fixing techniques. It will be appreciated the first surface 2a of the substrate 2 will in this example be in bonded contact with the underside of the cover layer 14, but appears separated in FIG. 2 because of the exaggerated thickness of the first electrode 8. The cover layer 14 may comprise any suitable material, for example a glass or plastics material.

The displacement element 3 is movably mounted relative to the frame element 12. In this example the movable mounting is provided by virtue of the displacement element 3 being bonded to the cover layer 14 which is itself movably mounted relative to the frame element 12. In this example the cover layer 14 is movably mounted to the frame element by virtue of a resiliently compressible support element 16 which is arranged to extend generally around the periphery of the cover layer 14 to encompass the displacement element 3. An upper edge of the support element 16 is bonded to the underside of the cover layer 14 and a lower edge of the support element 16 is bonded to the frame element 12. The support element 16 in this example is thus generally in the form of a rectangular ring arranged around the displacement element 3. The support element is shown with a simple rectangular cross-section in FIG. 2, but it will be appreciated that other shapes can be used in accordance with established mounting practices. For example, the support element may have a cross-section including a shoulder that extends under the displacement element 3. Thus, the support element 16 may in principle play a role of holding the displacement element 3, and hence the first and second electrodes, in position relative to the frame element 12 in addition to supporting the cover layer 14. More complex shapes for the support element 16 may be chosen, for example to provide different degrees of compressibility according to the degree to which the support element is already compressed. Although not shown in FIG. 2, the displacement sensor 1 may also be provided with a stop to limit the extent to which the support element 16 may be compressed (i.e. to limit the extent to which the displacement element may be displaced relative to the frame element 12). Such a stop may, for example, be provided by a suitably arranged protrusion of the frame element 12.

It will be appreciated the support element 16 need not be a single component extending all around the displacement sensor, but may comprise a number of separate components, for example, corresponding to a number of separate support pillars arranged around the displacement sensor, for example with one at each corner of the cover layer. It will also be appreciated other configurations may be used for the resiliently compressible support element 16, for example, the support element may comprise one or more springs.

Although in this particular example the support element 16 is shown bonded to the cover layer 14, in other implementations the support element 16 could equally be bonded directly to the displacement element 3 (for example the case where there is no cover layer, or where there is a cover layer but it does not overhang the displacement element 3). In any event, conventional bonding techniques can be used for bonding the support element 16 to the other parts of the displacement sensor, for example having regard to bonding techniques appropriate for the materials involved.

In this example the support comprises an elastomeric material having an appropriate degree of rigidity and compressibility according to the application. In some cases there may be a desire for a material having relatively low compressibility, thereby requiring a relatively high load to generate a given displacement of the displacement element relative to the frame element 12. Conversely, in some cases there may be a desire for a material having relatively high, compressibility, thereby requiring a relatively low load to generate a given displacement of the displacement element relative to the frame element 12. This will be a question of design choice. For example, in the context of displacement sensor forming a user interface a designer may choose how hard the user must press to cause a given displacement. This may be done, for example, to balance the risk of accidental activation against requiring too great a force for activation. A material having the desired degree of compressibility may be selected from modelling or empirical testing, for example.

The frame element 12 provides a structural support for the displacement sensor and will typically be connected to, or comprise an integral part of, an apparatus in which the displacement sensor 1 is provided. The frame element 12 provides a frame electrode 6, which may also be referred to as a reference electrode 6 since it in effect defines the reference position relative to which the displacement of the displacement element 3 is measured. The frame electrode 6 is an arrangement which generally aligns with the first and second electrodes in the overlying displacement element 3. In some implementations the frame element 12 may be made of a metallic material, and in this case a part of frame element 12 itself underlying the second electrode 12 inherently provides the functionality of the reference electrode 6. In other cases the frame material may be non-conductive, and the reference electrode 6 may thus comprise a separate conductive element mounted to the frame element. In this case the reference electrode 6 may comprise a conductive material deposited on the surface of the frame element 12 or may comprise a discrete element that is fixed to the frame element.

The frame element 12 in this example is assumed to comprise a metallic material corresponding to a part of a housing of an apparatus in which the displacement sensor 1 is being used. The frame element 12 is arranged to provide a recess into which the displacement element 3, support element 16, and cover layer 14 are received. The base of the recess is shown open in FIG. 2, and although not relevant for this example in which the displacement element 3 is not transparent, in other examples the open recess can allow for a display screen to be arranged behind the displacement element 3. In such cases the display screen may be mounted to the displacement element 3, so that it moves with it, or may be mounted to the frame element, so that it does not move with the displacement element 3.

The recess is sized so the upper surface of the cover layer 14 aligns with the upper surface of the frame element 12 with a small gap therebetween, thereby giving the general impression of a continuous outer surface for the apparatus in which the displacement sensor 1 is incorporated. If desired, a flexible seal may be provided to block the gap between the cover layer 14 and surrounding surface of the frame element 12. More generally, it will be appreciated there are various structural configurations whereby a frame element may be arranged to support a displacement element 3 in such a way that the displacement element and frame element are movable relative to one another in accordance with established manufacturing techniques.

Thus, having described the structural configuration of displacement sensors in accordance with certain embodiments of the mention, the operation of the split in sensor will now be described in regard to the functionality provided by the control element 4. The controller element 4 comprises capacitance measuring circuitry 4a and processing circuitry 4b. The capacitance measuring circuitry 4a is configured to measure a capacitance characteristic of the second electrode 10 and the processing circuitry 4b is configured to determine a displacement of the displacement element 3 relative to the frame electrode 6 based on measurements of the capacitance characteristic of the second electrode 10. There are various ways in which this can be done, as explained further below.

The controller element 4 comprises circuitry which is suitably configured/programmed to provide the functionality described herein using conventional programming/configuration techniques for capacitive sensors. The capacitance measuring circuitry 4a and a signal processing circuitry 4b are schematically shown in the figures as separate elements for ease of representation. However, it will be appreciated that the functionality of these components can be provided in various different ways, for example using a single suitably programmed general purpose computer, or field programmable gate array, or a suitably configured application-specific integrated circuit(s)/circuitry or using a plurality of discrete circuitry/processing elements for providing different elements of the desired functionality.

The capacitance measurement circuitry 4a is coupled to various ones of the first electrode 8, second electrode 10, and reference electrode 6 in different ways according to different embodiments, as discussed further below. Connections between the capacitance measurement circuitry and the relevant electrodes can be established in accordance with conventional techniques, for example using appropriate wiring. In some example embodiments the first electrode 8 and/or the reference electrode 6 are connected to a reference potential, e.g. a system ground/earth potential, or other fixed reference potential. Again these connections can be established using conventional techniques. In principle connections to the reference potential could be made via the capacitance measurement circuitry, but could also be made directly and independently from the capacitance measurement circuitry. For simplicity the system reference potential may sometimes be referred to herein as a system ground or earth, but it will be appreciated the actual potential itself may be arbitrary and is not significant (e.g. it could be 0V, 5V or 12V, or any other value according to the implementation at hand)

The capacitance measurement circuitry 4a may operate to measure the relevant capacitance characteristic of the second electrode in accordance with to any conventional techniques. Furthermore, and according to different example embodiments, the capacitance measurement circuitry 4a may be configured to measure a self-capacitance of the second electrode 10 or a mutual-capacitance between the second electrode 10 and one or other of the first electrode 8 and reference electrode 6, or between different parts of the second electrode 10. The textbook Capacitive Sensors: Design and Applications by Larry K. Baxter, August 1996, Wiley-IEEE Press, ISBN: 978-0-7803-5351-0 [1] summarises some of the principles of conventional capacitive sensing techniques that may be used for measuring a capacitance characteristic in accordance with embodiments of the invention.

In accordance with a first embodiment the capacitance measurement circuitry 4a may be configured to measure a self-capacitance of the second electrode 10 while the reference electrode 6 is connected to a system reference potential. In accordance with conventional techniques, measuring the self-capacitance of the second electrode 10 may be performed by applying a drive signal to the second electrode 10 that varies in time relative to system ground and determining the extent to which the drive signal is capacitively coupled to system ground via conductive paths in the vicinity of the second electrode that are connected to the system ground potential. Accordingly, for arrangements in accordance with embodiments of the invention such as represented in FIG. 2, the presence of the reference electrode 6 provides a significant contribution the extent to which the second electrode 10 is capacitively coupled to ground. Furthermore, the magnitude of this capacitive coupling depends on the separation (offset) between the second electrode 10 and the reference electrode 6. Therefore, this self-capacitance changes when the displacement element 3 is displaced under load. The processing circuit 4b is configured to receive indications of the measured capacitance characteristic of the second electrode from the capacitance measurement circuitry 4a, and determine a displacement of the displacement element 3 relative to the frame element 12 (more particularly relative to the reference electrode 6) in response thereto.

In some cases the processing circuitry 4b may be configured to determine an absolute value for a displacement, for example by converting an individual capacitance measurement (or average of several capacitance measurements) to a displacement offset based on a calibration function. The calibration function may, for example, be based on modelling or established in an initial setup procedure in accordance with conventional capacitance measurement techniques. In particular, a baseline value (corresponding to a measurement of the relevant capacitance characteristic of the second electrode when there is no displacement) may be established at various times, for example when the displacement sensor is initially turned on. The calibration function may then be used to convert differences in capacitance measurement from the baseline measurement to corresponding displacements.

In other cases, the processing circuitry may be configured to in effect provide a binary indication as to whether or not there has been a displacement greater than a threshold displacement. For example, the processing circuitry may be configured to identify when there has been a change in measured capacitance that is greater than a pre-defined trigger threshold, and to determine that this corresponds with a displacement by more than an amount corresponding to the pre-defined threshold displacement. An appropriate value for the pre-defined trigger threshold in any given implementation can be established empirically having regard to the extent of displacement which is desired to trigger a determination that displaced has occurred, and may be dynamically chosen to suit a given application.

The processing circuitry 4b may further be configured to provide an output signal (“O/P”) indicating the status regarding the displacement determination. This may be provided, for example, to a controller of a host apparatus in which the displacement sensor 1 is arranged. It will be appreciated the response of the host apparatus to the output from the controller element 4 is clearly purely an implementation matter and will depend on the reason why the displacement is being sensed in any given application. That is to say, it is not significant to the principles of displacement sensing as described herein.

In addition to applying the time-varying drive signal to the second electrode 10, the capacitance measurement circuitry 4a is configured to apply a corresponding drive signal to the first electrode 8. This reduces the sensitivity of the measured capacitance characteristic of the second electrode to an object at or above the displacement element 3 (e.g. a user's fingers applying load) by using the principle of guarding. In a variation the first electrode may instead be connected to system ground to screen the effect of objects above the displacement element 3 on the measurement of the self-capacitance of the second electrode 10.

Accordingly, the provision of the first electrode plays an important role in helping to reduce the sensitivity of the capacitance measurements of displacement from being affected by the presence of the object causing the displacement.

In accordance with a second embodiment the capacitance measurement circuitry 4a may be based on a mutual-capacitance measurement approach. In this configuration, the capacitance measurement circuitry may be configured to apply a time-varying drive signal to the first electrode 8 and to measure the extent to which the drive signal is capacitively coupled to the second electrode 10, again using conventional capacitance measurement techniques. The reference electrode 6 is connected to the system ground/reference potential. The proximity of the reference electrode 6 thus impacts the extent to which the drive signal is capacitively coupled between the first and second electrodes, thereby making the measurements obtained by the capacitance measurement circuitry sensitive to the displacement of the displacement element 3 relative to the frame element 12/reference electrode 6. Furthermore, for this type of drive-receive measurement scheme, the presence of an object on the opposite side of the driven electrode (the first electrode 8 in this case) to the receive electrode (the second electrode 10 in this case) does not significantly affect the extent to which the drive signal is capacitively coupled from the driven electrode to the receive electrode. Accordingly, this approach can also help to reduce the sensitivity of the capacitance measurements of displacement from being affected by the presence of the object causing the displacement.

The processing circuitry 4b may be configured to receive and process measurements from the capacitance circuitry 4a in accordance with this mutual-capacitance based example embodiment in the same manner as described above for the self-capacitance based example embodiment.

It will be appreciated there are various further combinations with regards to how the capacitance measurement circuitry may be coupled to the various electrodes of the displacement sensor 1. For example, in a variation of the mutual-capacitance based example embodiment discussed above, the capacitance measurement circuitry may be configured to apply a time-varying drive signal to the reference electrode 6 and to measure the extent to which the drive signal is capacitively coupled to the second electrode 10, again using conventional capacitance measurement techniques. The first electrode 10 is connected to the system ground/reference potential. The extent to which the drive signal is coupled from the reference electrode 6 to the second electrode 10 depends on the offset between them (i.e. the displacement of the displacement element relative to the frame element 12), thereby making the measurements obtained by the capacitance measurement circuitry sensitive to the displacement of the displacement element 3 relative to the frame element 12/reference electrode 6. Having the first electrode 8 connected to the reference potential in this configuration again provide screening to help reduce the sensitivity of the capacitance measurements of displacement from being affected by the presence of the object causing the displacement.

In yet another example, the displacement sensor may have a generally similar configuration to that described above, but the second electrode may in effect be split into a first part and a second part having a capacitive coupling between them, for example comprising a first part and a second part adjacently arranged around the peripheral part of a displacement element. Capacitance measurement circuitry may then be configured to measure the extent to which a drive signal applied to the first part is coupled to the second part of the reference electrode is connected to system ground. The extent to which the drive signal is coupled from the first part to the second part of the second electrode will be affected by the distance to the reference electrode in much the same way as described above for the configuration in which a drive signal is applied to the first electrode and received on the second electrode. The first electrode in this configuration may thus be grounded to again screen the capacitance measurements from external objects. The measurements of capacitive coupling between the first and second part of the second electrode can then be handled in the same manner as described above. This style of mutual measurement is sometimes referred to a “transverse” arrangement in recognition of the fact the coupled electric fields between the two parts of the split second electrode are generally oriented in a transverse manner relative to their supporting substrate.

Thus, and will be understood by those skilled in the art, there are various different ways in which the electrodes can be driven to measure very different capacitance characteristics associated with the second electrode. Furthermore, it will be appreciated the use of three electrodes can help reduce the sensitivity of the displacement sensor to objects approaching the displacement sensor.

There are various modifications to the approaches described above that can be adopted. For example, in some cases the region of the substrate 2 inside the peripheral parts containing the first and second electrodes could be provided with a conventional capacitive touch-panel sensor. This may be provided using a suitably arranged electrode pattern deposited on the first surfaced 2a and/or on the second surface 2b of the substrate away from the peripheral parts containing the first and second electrodes discussed above. The electrode pattern for the touch-panel aspect may be provided in accordance with conventional techniques.

Furthermore, the touch-panel component may also overlay a display (in cases where the various elements overlying the display are transparent). Thus, a capacitive touchscreen featuring displacement sensing can be provided.

It will also be appreciated that the approaches described above have focused on individual electrodes which may have individual connections to the control circuitry and/or reference potential as appropriate. Nonetheless, the respective electrodes can in principle be divided into multiple parts with separate connections to the control circuitry and/or reference potential. For example, the second electrode may comprise two separate parts which together extend around at least a major portion of the outer periphery of the displacement sensor, and each part may be connected to a separate capacitive characteristic measurement channel (or in parallel or multiplexed manner to a single capacitive characteristic measurement channel), with the outputs from the separate measurement channels being combined to provide an indication of the combined capacitive characteristics of the different parts forming the second electrode.

It will further be appreciated that there can be various modifications made to the specific geometries discussed above. In this regard, FIG. 3 schematically shows in plan-view a displacement element 30 for use in a displacement sensor according to another embodiment of the invention. The plan-view of the displacement element 30 represented in FIG. 3 differs from that of the displacement element 3 represented in FIG. 1A in that FIG. 3 shows a view from below (i.e. a view from the side of the second electrode). Various aspects of the displacement element 30 of FIG. 3 are similar to those of the displacement element 3 discussed above, and are not repeated here in the interest of brevity. In particular, the principles of operation for a displacement sensor comprising the displacement element 30 of FIG. 3 and a displacement sensor 1 comprising the displacement element 3 of FIGS. 1A, 1B and 2 can be the same.

However, the general shape of the displacement sensor of FIG. 3 is different from described above. Thus, the displacement element 30 again comprises a substrate 32 having a first surface and a second surface. The substrate 32 again defines the general overall shape of the displacement element 32, but is in this example in the form of a planar circle. The size of the substrate may again be chosen according to the implementation at hand (i.e. the desired size of the displacement sensor). Purely for the sake of a specific example, it will be assumed here the substrate has a size of around 10 cm (diameter)×0.5 cm (thickness). The first and second surfaces of the substrate 2 are the opposing largest faces.

In addition to having a different overall shape, the first and second electrode configurations for the example represented in FIG. 3 are different from that represented in FIGS. 1A, 1B and 2.

Thus a first electrode 38 is provided at the periphery/in a peripheral part of the first surface (lowermost in FIG. 3) of the substrate 32 (i.e. adjacent to/in the vicinity of an outer edge of the first surface 2a). In this particular example the first electrode 38 forms a substantially closed (i.e. completely or nearly closed path around the entire periphery of the substrate and has a uniform width of around 1 cm starting from the outer edge of the first surface. However, it will again be appreciated the specific geometry of the first electrode, e.g. in terms of its width and separation from the edge of the first surface 2a and the extent to which it extends around the whole periphery, may be different in different implementations.

A second electrode 40 is provided at the periphery/in a peripheral part of the second surface (uppermost) the substrate 2 (i.e. adjacent to/in the vicinity of an outer edge of the second surface 2b). The arrangement of the second electrode 40 on the second surface is different from the arrangement of the first electrode 38 provided on the first surface. That is to say, the two electrodes do not have the same shape, although they are generally in alignment (with regards to a direction perpendicular to the substrate) with the first electrode 38 having an extent that covers and goes beyond/overhangs the extent of the second electrode 40 when viewed from above (hence the first electrode is visible in the plan view of FIG. 3). This can help to further increase the screening/guarding effect of the first electrode. The second electrode 40 in this example comprises a series of forms in the areas 41 indicated by conductive traces 39. This arrangement can, for example, be beneficial where constraints caused by other features on the substrate 2 limit the available space around the periphery of the same for the second electrode, so making it beneficial to form interconnected “islands” of conductive material instead, where space allows for these larger features.

It will be appreciated that whilst the above-described embodiments have focused on displacement sensing in the context of providing a user interface, the same principles can be applied more generally wherever there is a desire to measure the displacement of one object relative to another. For example, principles similar to those described above may be used for general switching/displacement indication applications, and furthermore, it will be appreciated the displacement may not be due to activation by a user. For example, in some implementations the same techniques can be used to measure whether one components of an apparatus has moved relative to one another component. In the most general sense, it will be appreciated the reasons why a displacement is being measured in any given implementation, and any actions taken in response whether or not a displacement is measured, are not significant to the principles described herein.

It will be further appreciated that while specific materials and dimensions for various elements have been provided by way of specific example, in general the materials and overall geometry of the elements comprising the displacement sensor may be selected according to the application at hand, example accords with a large or small area displacement sensor is desired. The exact arrangement adopted for any specific information may be determined empirically, for example by testing the response of different configurations and selecting a configuration providing a desired response (for example in terms of sensitivity/rejection of spurious displacement detections). It will be further realized that while the above descriptions have focussed on planar structures for the cover element 14 and displacement element 3, the principles described herein are equally applicable to non-planar structures for these elements too. For example, the scheme could be used to sense displacement on a touch sensitive system that incorporates a curved outer cover layer.

Thus there has been described a displacement sensor comprising: a reference electrode; and a displacement element movably mounted relative to the reference electrode and comprising a substrate having first and second opposing surfaces with a first electrode arranged around a peripheral part of the first surface (e.g. extending around at least a majority of the periphery of the displacement element to form a substantially closed path, for example so the electrode extends around at least 50%, 60%, 70%, 80%, 90% or 95% of the periphery of the displacement element) and a second electrode arranged around a peripheral part of the second surface (e.g. extending around at least a majority of the periphery of the displacement element to form a substantially closed path, for example so the electrode extends around at least 50%, 60%, 70%, 80%, 90% or 95% of the periphery of the displacement element), and wherein the reference electrode on the same side of the substrate as the second electrode and offset therefrom; and a controller element configured to measure a capacitance characteristic of the second electrode at different times and to determine whether there has been a displacement of the displacement element relative to the reference electrode based on whether there has been a change in the capacitance characteristic of the second electrode.

Accordingly, some aspects of some example displacement sensing apparatus and methods according to some embodiments may be summarised as follows.

A displacement sensor is disclosed that can be integrated with various touch panel structures or with any surface that is to be made reactive to displacement by the application of a load. The system uses a pair of electrodes, driven so as to sense changes in capacitance caused by a varying displacement of one of the electrodes relative to a conductive structural reference frame. The electrodes may be formed substantially around the periphery of the sensor and hence integrate the total displacement caused by an applied load.

More particularly in accordance with some example implementations, a pair of electrodes (comprising first and second electrodes) is formed around the outer edges of an item for which displacement is to be sensed. For simplicity this may sometimes be referred to as a “displacement element” for the sensor. The displacement element is typically, but not necessarily, further mounted behind an outer cover layer. In the case the displacement element further provides a touch-sensitive panel for instance, this could provide an outer glass layer which the user touches (to provide input to the touch-sensitive panel) and presses (to provide a displacement input to the displacement sensor). In the general case however, whether or not the sensor includes an outer cover layer is not significant to the process of sensing displacements in accordance with the principles described herein. What is significant in accordance with some embodiments of the invention is that the pair of electrodes is part of a structure which is displaceable relative to a mechanical reference point when a load is applied to the upper surface.

To allow the sensor to be displaced, it may in some examples be mounted using a semi-rigid material to an internal structural frame using one or more support piece(s). The support piece(s) can serve several purposes. For example: the support piece(s) can hold the sensor and frame assembly together to make a unitary module; the support piece(s) can provide a seal around (possibly all) the periphery of the sensor and frame to help exclude water, liquids and dust from the interior of the assembly. The support piece(s) can be configured to provide sufficient compressibility to allow small displacements of the sensor relative to the frame, for example in some cases the order of a few micro-meters.

By arranging the electrodes around the periphery of the sensor, the total change in the volume of space between the second electrode (arranged to face the frame) and the frame, will be approximately constant regardless of the point of application of the load on the upper surface. If an activation load (e.g. a user pressing) is applied around the centre of the displacement element, there can be expected to be an approximately equal reduction in “D” (the offset between the second electrode and a reference electrode provided by the frame) around the whole periphery, for example a reduction on the order of “ΔD”. However, if the same activation load (e.g. same force of user pressing) is applied near to one edge of the displacement sensor, there will be a non-uniform displacement of the second electrode relative to the frame (i.e. it will be tilted). On the side near the load the displacement will typically be greater than “ΔD” and on the side away from the load the displacement will typically be less than “ΔD”. The inventors have recognised effect of the displacement when averaged across the area of the second electrode is broadly the same (because there is broadly same change in the volume of space between the electrode and the frame). Furthermore, by having a single second electrode extend around a closed path (or at least a major part of a closed path) in a peripheral part of the displacement element, this relative uniformity of response to displacement forces applied at different positions on the substrate may be achieved using only one capacitive sense channel in the controller unit and one corresponding connection to the second electrode. Likewise, providing a single first electrode extending around a closed path (or at least a major part of a closed path) in a peripheral part of the displacement element allows for only one connection to the upper surface of the substrate of the displacement element. In this regard approaches in accordance with certain embodiments of the invention can help to simplify production and reduce manufacturing and parts costs.

To sense a displacement, a measurement circuit is coupled to the first and second electrodes. The second electrode is coupled to a Capacitance to Digital (C-to-D) converter in order to measure a capacitance characteristic of the second electrode. In this regard, the measurement circuitry maybe conventional according to any of the well-known approaches for measuring capacitance. The circuit may use either a “self-capacitance” or “mutual capacitance” method to undertake the relevant measurements. A self-capacitance measurement may be preferred in some implementations as the nature of the electric fields formed between the second electrode and the reference frame (connected to a reference potential, such as 0V or to “ground”/“earth”) is such that it will tend to maximise the change in electrical capacitance is a function of displacement. In the case of a mutual capacitance measurement, the change in capacitance can be smaller than in the case of a self-capacitance measurement because the electric field that can be influenced by the proximity of the frame to the electrodes is reduced, there being only a portion of the leakage or “fringe” field between the electrodes that reaches the frame, and hence can change the electrode's mutual coupling when they are moved relative to the frame.

In the case of a self-capacitance measurement system, the first electrode may be connected to a drive circuit to help guard the second electrode. In accordance with this approach, an electrical stimulus which substantially matches that used to measure the capacitance of the second electrode is also applied to the first electrode. This has the effect of helping to electrically “hide” the second electrode behind the first, so that changes in capacitive coupling associated with the first electrode (e.g. caused by presence of an object near to/activating the displacement sensor) has a reduced effect the capacitance of the second electrode. This can be important in the case of some touch panel systems, as it means that the second electrode's capacitance is less affected by a touch placed over the first electrode i.e. the displacement sensor can be made less sensitive to touches from the top surface. A similar result can be achieved if the first electrode is connected to a reference potential (such as the same reference potential as for the frame) to provide screening the second electrode. Thus in some examples the first electrode may be connected to either a time-varying drive signal (e.g. matching that applied to the second electrode) or a reference potential (e.g. matching that of the frame—or at least the part of the frame providing the function of a reference (frame) electrode as discussed above).

In the case of a mutual capacitance measurement system, in some examples the first electrode may instead carry an excitation drive waveform for causing charge to flow in and out of the second electrode. Changes in displacement would cause some amount of this charge to be diverted from the second electrode instead into the frame, and hence cause a measureable change in coupling between the first and second electrode. In other examples, the first electrode may instead be connected to a reference potential while an excitation drive waveform for causing charge to flow in and out of the second electrode is applied to the frame (or at least the part of the frame providing the function of a reference (frame) electrode as discussed above). The degree of drive signal coupling from the frame to the second electrode changes as the distance between them changes, thereby allowing a displacement to be detected. In general, it can be expected the frame part of the displacement sensor will be connected to a larger housing of an apparatus (e.g. a computer or any other apparatus employing a displacement sensor in accordance with the principles described herein), and as such it may in some cases be preferable to take approaches in which the frame is connected to a reference potential, rather than to a drive signal.

The measurement system provided by the controller element may typically include a suitably programmed microprocessor or suitable processing logic, to allow it to filter and adjust the raw measurements from the capacitive sensor in accordance with established capacitive sensing techniques. The processing function may include calibration functionality, for example to store a “baseline” displacement measurement, e.g. obtained on initial power-on or reset, or in response to instructions from a host apparatus in which the displacement sensor is being used. The signal processing functionality may also include measurement trimming to compensate for environmental changes that can in some situations affect the displacement sensor's raw signals, making them drift over time. Again, these signal processing techniques may be based on the established principles of capacitive sensing techniques and circuitry.

The measurement system/controller element may also provide a host interface to allow it to output an indication of a measured displacement to a host processing system for a host apparatus in which the displacement sensor is arranged. The host may therefore establish an absolute or relative displacement associated with the displacement sensor and use this as either a primary measurement for control of a specific function of the host apparatus, or it may use it used it to augment another function. For example, in a touch panel system, the host apparatus may use the displacement measurement to help determine a user's intention when making selections. For example, the position of a user's touch may come from a 2D touch panel controller associated with an 2D electrode array in a middle region of the displacement sensor, while a measurement of displacement coming from the peripheral electrodes as described above to indicate a user's selection (“click”) associated with the position of the user's touch.

The controller element/measurement system may be configured to make measurements of the relevant capacitive characteristic of the second electrode at an appropriate sampling rate having regard to the timescales on which the display is to be measured are expected to occur. For example, in the case of a user interface the sampling rate may correspond with that typically used for user input devices (e.g. corresponding to the rate at which the state of a mouse click button would be sampled in the context of the implementation hand). The displacement sensor could also be used for other applications, for example to measure the rate at which something is vibrating, and in this case a sampling period according to the expected vibration rates may be chosen, for example allowing for the sensing of displacements varying in time with frequency components up to a few 100 Hz. In some cases, it may the controller element/measurement system may be configured to adopt an approach of measuring capacitance (and hence displacement) using an AC coupled system, meaning that the C-to-D converter does not directly measure a static displacement. However by appropriate post processing, either in the measurement system's microprocessor, or in the host system, a static (DC) element to the displacement between the sending element and frame can be approximated, e.g. through integration measurements obtained over time.

Further particular and preferred aspects of the present invention are set out in the accompanying independent and dependent claims. It will be appreciated that features of the dependent claims may be combined with features of the independent claims in combinations other than those explicitly set out in the claims.

### REFERENCES

[1] Capacitive Sensors: Design and Applications by Larry K. Baxter, August 1996, Wley-IEEE Press, ISBN: 978-0-7803-5351-0

1. A displacement sensor comprising:
a reference electrode; and
a displacement element movably mounted relative to the reference electrode and comprising a substrate having first and second opposing surfaces with a first electrode arranged around a peripheral part of the first surface and a second electrode arranged around a peripheral part of the second surface, and wherein the reference electrode is on the same side of the substrate as the second electrode and offset therefrom; and
a controller element configured to measure a capacitance characteristic of the second electrode to determine a displacement of the displacement element relative to the reference electrode from the measured capacitance characteristic of the second electrode.

2. The displacement sensor of claim 1, further comprising a frame element to which the displacement element is movably mounted.

3. The displacement sensor of claim 2, wherein the reference electrode is provided by the frame element.

4. The displacement sensor of claim 3, wherein the frame element comprises a conductive material and/or has a conductive material disposed thereon to provide the reference electrode.

5. The displacement sensor of claim 2, wherein the displacement element is movably mounted to the frame element using a resiliently compressible support element.

6. The displacement sensor of claim 5, wherein the displacement element and/or the frame element are bonded to the support element.

7. The displacement sensor of claim 5, wherein the support element extends around the periphery of the substrate element to provide a seal for the displacement sensor.

8. The displacement sensor of claim 1, further comprising a cover panel arranged over the substrate on the same side of the substrate as the first electrode.

9. The displacement sensor of claim 1, wherein the first and/or second electrodes form a closed path.

10. The displacement sensor of claim 1, wherein the second electrode comprises regions of different widths on the substrate at different positions around the substrate.

11. The displacement sensor of claim 10, wherein the second electrode comprises a series of primary sensing regions linked by conductive traces which are narrower than the primary sensing regions.

12. The displacement sensor of claim 1, wherein the first electrode has an extent on the substrate which substantially covers the extent of the second electrode.

13. The displacement sensor of claim 12, wherein the first electrode has an extent on the substrate which goes beyond the extent of the second electrode.

14. The displacement sensor of claim 1, configured such that the reference electrode and/or the first electrode is connected to a reference potential when the capacitance characteristic of the second electrode is being measured.

15. The displacement sensor of claim 1, wherein the controller element is configured to measure the capacitance characteristic of the second electrode with respect to the reference electrode by measuring the second electrode's response to a time-varying drive signal applied to the second electrode.

16. The displacement sensor of claim 15, configured such that the first electrode is connected to a reference potential when the capacitance characteristic of the second electrode is being measured.

17. The displacement sensor of claim 15, wherein the controller element is configured to apply a time-varying drive signal to the first electrode based on the time-varying drive signal applied to the second electrode when the capacitance characteristic of the second electrode is being measured.

18. The displacement sensor of claim 1, wherein the controller element is configured to measure the capacitance characteristic of the second electrode by applying a time-varying drive signal to the first electrode and/or the reference electrode and measuring the extent to which the drive signal is coupled to second electrode.

19. The displacement sensor of claim 1, wherein the controller element is configured to measure the capacitance characteristic of the second electrode by applying a time-varying drive signal to the second electrode and measuring the extent to which the drive signal is coupled to the reference electrode.

20. The displacement sensor of claim 1, wherein the second electrode comprises a first part and a second part, and wherein the controller element is configured to measure the capacitance characteristic of the second electrode by applying a time-varying drive signal to one of the first and second parts of the second electrode and measuring the extent to which the drive signal is coupled to the other of the first and second parts of the second electrode.

21. The displacement sensor of claim 1, wherein the capacitance characteristic of the second electrode comprises an indication of the second electrode's mutual-capacitance with respect to the first electrode and/or reference electrode.

22. The displacement sensor of claim 1, wherein capacitance characteristic of the second electrode comprises an indication of the second electrode's self-capacitance.

23. The displacement sensor of claim 1, wherein the controller element is further configured to generate an output signal to indicate when it determines there has been a displacement of the displacement element relative to the reference electrode.

24. The displacement sensor of claim 1, wherein the control element is configured to determine there has been a displacement of the displacement element relative to the reference electrode by comparing a difference between two measurements of the capacitance characteristic with a trigger threshold.

25. The displacement sensor of claim 1, further comprising a position-sensitive capacitive touch sensor having an electrode pattern defining a sensitive area for the position-sensitive capacitive touch sensor on the substrate.

26. An apparatus comprising the displacement sensor of claim 1.

27. A method of sensing displacements, comprising:
providing a reference electrode;
providing a displacement element movably mounted relative to the reference electrode and comprising a substrate having first and second opposing surfaces with a first electrode arranged around a peripheral part of the first surface and a second electrode arranged around a peripheral part of the second surface, and wherein the reference electrode is on the same side of the substrate as the second electrode and offset therefrom;
measuring a capacitance characteristic of the second electrode; and
determining a displacement of the displacement element relative to the reference electrode from the measured capacitance characteristic of the second electrode.

28-29. (canceled)
